(19) United States
(12) Patent Application Publication
(10) Pub. No.: US 2010/0271103 A1
(43) Pub. Date: Oct. 28, 2010

(54) SEMICONDUCTOR INTEGRATED CIRCUIT DEVICE

(75) Inventors: Nao Miyamoto, Ome (JP); Tatsuhiro Aida, Hino (JP); Shinobu Yabuki, Hamura (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/429,172

(22) Filed: Apr. 23, 2009

(51) Int. Cl. H03L 5/00

(52) U.S. Cl. 327/333

(57) ABSTRACT

When a high-voltage output is Hi, a first N-type transistor and a second P-type transistor are in an OFF state, and a second N-type transistor and a first P-type transistor are in an ON state, where a high voltage is applied to drain-source of the first N-type transistor. In a process to shift the high voltage output to Lo, a gate potential of the first N-type transistor is once put to an intermediate state between VDD and GND to lower a drain-source voltage of the first N-type transistor, then the gate potential is raised to VDD. In this manner, a state where the drain-source voltage of the first N-type transistor is large and also a drain current of the same is large is avoided, so that an On withstand voltage of the level shift circuit is increased, thereby preventing a breakdown.

### CROSS-REFERENCE TO RELATED APPLICATION

The present application claims priority from Japanese Patent Application No. JP 2008-114770 filed on Apr. 25, 2008, the content of which is hereby incorporated by reference into this application.

### FIELD OF THE INVENTION

The present invention relates to a semiconductor integrated circuit device. More particularly, the present invention relates to a semiconductor integrated circuit on which a load driving circuit and a level-shift driving circuit which drives a level-shift circuit composing the load driving circuit are integrally formed on a common semiconductor substrate. Alternatively, the present invention relates to a scan-driver semiconductor integrated circuit device for a plasma display provided with a plurality of channels for combinations of a load driving circuit and a level-shift driving circuit.

### BACKGROUND OF THE INVENTION

Conventionally, there has been such a problem upon turning on a power MOS transistor that, when a device having a not high withstand voltage is used, it is led to a breakdown when a high voltage is applied across a gate and a source. Accordingly, there has been proposed a buffer circuit as a driving circuit which is operated by a voltage between a source of a P-type MOS transistor whose gate is connected to a voltage circuit and a power supply terminal, and drives a power MOS transistor (e.g., refer to Japanese Patent Application Laid-Open Publication No. 2005-101747 (Patent Document 1)).

### SUMMARY OF THE INVENTION

The inventors of the present invention have studied about a method of driving a level shift circuit prior to the present application. As to the level shift circuit, they have studied a circuit which drives a level shift circuit of a differential N-type MOS transistor by a simple inverter such as one illustrated in FIG. 9.

Meanwhile, the inventors of the present application have found that an ON withstand voltage of the differential N-type MOS transistor has not been taken into account in this circuit. A level shift 9 is composed of N-type transistors HVN2 and HVN1, and P-type transistors HVP2 and HVP1. A drain terminal of the N-type transistor HVN1 is connected to a gate of a switching element 1. The switching element 1 has a size large enough to withstand a load driving for driving external loads, and generally, its gate capacitance is also large. Thus, a load for the N-type transistor HVN1 to drive is large. On the other hand, since the N-type transistor HVN2 drives a gate of the P-type transistor HVP1 of the level shift circuit, a load for the N-type transistor HVN2 to drive is small.

When a high voltage output DOUT is at the Hi level (high level), the N-type transistor HVN1 is in an Off state, and the P-type transistor HVP2 is in an On state. At this moment, a high voltage VH is being applied across drain-source of the N-type transistor HVN1. To shift the high voltage output DOUT from the Hi level to the Lo level (low level), control for applying a low voltage VDD across gate-source of the N-type transistor HVN1 is performed. Immediately after applying the low voltage VDD across the gate-source, the high voltage VH is being applied across drain-source, and a potential of a node G is gradually lowered to the Lo level by driving the N-type transistor HVN1. Since the gate capacitance of the switching element 1 is included in the load to be driven by the N-type transistor HVN1, a drain current reaches a saturation current before a drain-source voltage Vds of the N-type transistor HVN1 is lowered. Therefore, the N-type transistor HVN1 has a state in which the voltage across drain-source is large and the drain current is large. Accordingly, the circuit becomes inoperative when a margin of the On withstand voltage of the N-type transistor HVN1 is small.

An operating point of the N-type transistor HVN1 is illustrated in FIG. 10. The drain-source voltage Vds is depicted on the horizontal axis and the drain current Ids is depicted on the vertical axis. The curve from a point A at which Vds=VH, Ids=0 reaches a point C at which Vds=0, Ids=0 via a point B at which the drain current Ids reaches the saturation current. At the point B, the drain-source voltage is large and the drain current is large, and thus the N-type transistor HNV1 becomes inoperable when the On withstand margin is small.

On the other hand, since the P-type transistor HVP2 drives a small load, the drain-source voltage Vds is lowered before the drain current Ids reaches the saturation current. Therefore, the P-type transistor HVP2 does not have a state in which the drain-source voltage is large and the drain current is large.

An operating point of the N-type transistor HVN2 is illustrated in FIG. 11. The drain-source voltage Vds is depicted on the horizontal axis and the drain current Ids is depicted on the vertical axis. The curve from a point A at which Vds=VH, Ids=0 reaches a point C at which Vds=0, Ids=0 via a point B at which the drain current Ids reaches the saturation current. Since the drain-source voltage is decreased at the point B, the concern on the On withstand voltage margin is not necessary as compared with the N-type transistor HVN1.

Note that, while above-cited Patent Document 1 is an example of trying to solve the problem of device breakdown by newly providing a buffer circuit, it is considered that there is remained a problem in terms of the overhead of the whole of the circuit area for the area the newly-provided buffer circuit occupies.

One of the typical examples of the present invention is as follows. Specifically, a semiconductor integrated circuit device of the present invention is composed of: an output terminal; an output transistor connected to the output terminal; a load driving circuit including a level shift circuit that changes an input level of the output transistor; a level-shift driving circuit including a first inverter in which a second P-type MOS transistor whose source is connected to a first power supply and a first N-type MOS transistor whose source is connected to a second power supply whose potential is lower than that of the first power supply are connected via each other's drains; and an input terminal commonly connected electrically to gates of the second P-type MOS transistor and the first N-type MOS transistor composing the first inverter. The level shift circuit includes first and second load driving N-type MOS transistors whose sources are commonly connected to the second power supply, and a drain of the first load driving N-type transistor is connected to a gate of the output transistor. The level-shift driving circuit is connected to a gate of the first load driving circuit composing the level shift circuit through the common drain of the first inverter, and includes a level-shift driving voltage suppressing circuit which suppresses a voltage generated at the common drain of the first inverter.

From another view point, a semiconductor integrated circuit device is a circuit which supplies high and low voltages to a load, and the circuit composed of: a first semiconductor switching element between a high-voltage power supply and an output terminal; a second semiconductor switching element between the output terminal and a ground; a first high-voltage PMOS transistor driving a gate of the first semiconductor switching element; a first high-voltage NMOS transistor driving the gate of the first semiconductor switching element; a second high-voltage PMOS transistor differentially operated with the first high-voltage PMOS transistor; a second high-voltage NMOS transistor differentially operated with the first high-voltage NMOS transistor; and a configuration suppressing a voltage to be applied to a gate of the first high-voltage NMOS transistor.

In addition, a scan-driver semiconductor integrated circuit device of the present invention is a semiconductor integrated circuit device composed of a plurality of sets of circuits composed of: the output terminal; the load driving circuit; the level-shift driving circuit; and the input terminal, and the circuits are arranged in parallel and integrally formed on a common semiconductor substrate.

According to the present invention, a semiconductor device having a high On withstand voltage can be provided.

### BRIEF DESCRIPTIONS OF THE DRAWINGS

FIG. 1 is a diagram illustrating an embodiment (first embodiment) of a semiconductor integrated circuit device of the present invention;

FIG. 2 is an operation waveform diagram for describing an operation of FIG. 1;

FIG. 3 is an operational diagram for describing an operation of HVN1 in FIG. 1;

FIG. 4 is a diagram illustrating a modification example (first modification example) of the first embodiment of the present invention;

FIG. 5 is a diagram illustrating a modification example (second modification example) of the first embodiment of the present invention;

FIG. 6 is a diagram illustrating an embodiment (second embodiment) of a semiconductor integrated circuit device of the present invention;

FIG. 7 is an operation waveform diagram for describing an operation of FIG. 6;

FIG. 8 is a diagram illustrating a modification example (first modification example) of the second embodiment of the present invention;

FIG. 9 is a diagram illustrating an example of a conventional semiconductor integrated circuit device;

FIG. 10 is an operational diagram for describing an operation of HVN1 in FIG. 9;

FIG. 11 is an operational diagram for describing an operation of HVN2 in FIG. 9;

FIG. 12 is a diagram illustrating an embodiment (third embodiment) of a scan-driver semiconductor integrated circuit device composed of a plurality of sets of series connections of load driving circuits and level-shift driving circuits, in which the plurality of sets of these circuits are arranged in parallel; and

FIG. 13 is a diagram illustrating an embodiment (fourth embodiment) of a plasma display using a scan-driver semiconductor integrated circuit device of the present invention.

### DETAILED DESCRIPTION OF THE PREFERRED EMBODIMENTS

A semiconductor integrated circuit device of the present invention is composed of: an output terminal; a load driving circuit including an output transistor connected to the output terminal and a level shift circuit that changes an input level of the output transistor; a level-shift driving circuit including a first inverter in which a second P-type MOS transistor whose source is connected to a first power supply and a first N-type MOS transistor whose source is connected to a second power supply whose potential is lower than that of the first power supply are connected via each other's drains; and an input terminal commonly connected electrically to gates of the second P-type MOS transistor and the first N-type MOS transistor composing the first inverter. The level shift circuit includes first and second load driving N-type MOS transistors whose sources are commonly connected electrically to the second power supply, and a drain of the first load driving N-type transistor is connected to a gate of the output transistor. The level-shift driving circuit is connected to a gate of the first load driving circuit composing the level shift circuit through the common drain of the first inverter, and includes a level-shift driving voltage suppressing circuit which suppresses a voltage generated at the common drain of the first inverter.

The level-shift driving voltage suppressing circuit is preferable to include: a first P-type MOS transistor whose source is electrically connected to the first power supply, whose drain is connected to the common drain of the first inverter, and whose gate is connected to the input terminal; and a delay element whose output is commonly connected to the gates of the second P-type MOS transistor and the first N-type MOS transistor composing the first inverter, and whose input is connected to the input terminal.

The first P-type MOS transistor may be connected to the first power supply in series by its source, and for example, it is more preferable when the first P-type MOS transistor is electrically connected to the first power supply via a diode whose anode is connected to the first power supply and whose cathode is connected to the source of the first P-type MOS transistor.

The level-shift driving voltage suppressing circuit is preferable to include: a second N-type MOS transistor whose drain is electrically connected to the first power supply, whose source is connected to the common drain of the first inverter, and whose gate is electrically connected to the input terminal via a second inverter; and a delay element whose output is commonly connected to the gates of the second P-type MOS transistor and the first N-type MOS transistor composing the first inverter, and whose input is connected to the input terminal.

The level-shift driving voltage suppressing circuit is also preferable to include: a first P-type MOS transistor whose source is electrically connected to the first power source, whose drain is connected to the common drain of the first inverter, and whose gate is connected to the input terminal; a delay element whose output is connected to the gate of the second P-type MOS transistor composing the first inverter, and whose input is connected to the input terminal; and an AND gate element whose output is connected to the gate of the first N-type MOS transistor composing the first inverter, and whose input is connected to the input terminal and the output of the delay element. In this case, the first P-type MOS transistor is electrically connected to the first power supply via a diode whose anode is connected to the first power supply, and whose cathode is connected to the source of the first P-type MOS transistor.

The level-shift driving voltage suppressing circuit is also preferable to include: a second N-type MOS transistor whose drain is electrically connected to the first power source, whose source is connected to the common drain of the first inverter, and whose gate is electrically connected to the input terminal via a second inverter; a delay element whose output is connected to the gate of the second P-type MOS transistor composing the first inverter, and whose input is connected to the input terminal; and an AND gate element whose output is connected to the gate of the first N-type MOS transistor composing the first inverter, and whose input is connected to the input terminal and the output of the delay element.

From another view point, a semiconductor integrated circuit device of the present invention is a circuit which supplies high and low voltages to a load, the semiconductor integrated circuit device is composed of: a first semiconductor switching element connected between a first power supply and an output terminal; a second semiconductor switching element connected between the output terminal and a second power supply whose potential is lower than that of the first power supply; a first high-voltage PMOS transistor driving a gate of the first semiconductor switching element; a first high-voltage NMOS transistor driving the gate of the first semiconductor switching element; a second high-voltage PMOS transistor differentially operated with the first high-voltage PMOS transistor; a second high-voltage NMOS transistor differentially operated with the first high-voltage NMOS transistor; and a level-shift driving circuit including a first inverter in which a second P-type MOS transistor whose source is connected to the first power supply and a first N-type MOS transistor whose source is connected to the second power supply are connected via each other's drains, and a level-shift driving voltage suppressing circuit suppressing a voltage applied to a gate of the first high voltage N-type MOS transistor.

In the following, embodiments of the present invention will be described in detail with reference to the accompanied drawings. Although circuit elements composing respective blocks of the embodiments are not particularly limited, they are formed on one semiconductor substrate such as single crystal silicon by a known integrated-circuit technology such as CMOS (Complementary MOS transistor) process technology.

### First Embodiment

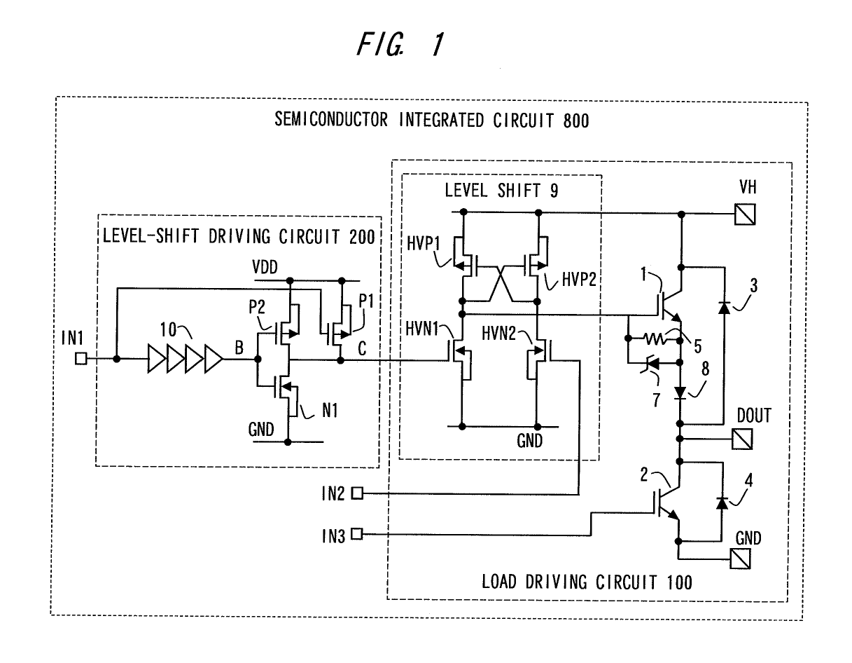

FIG. 1 is a diagram illustrating a first embodiment which is one example of a semiconductor integrated circuit device of the present invention. A semiconductor integrated circuit 800 of the present embodiment is composed of two parts, which are: a level-shift driving circuit to which a voltage VDD of about 5 V is applied; and a load driving circuit 100 to which a high power supply VH larger than or equal to 100 V is applied. Particularly, a configuration of the level-shift driving circuit 200 is characteristic. In the following, respective circuits will be described.

The load driving circuit 100 is composed of: a level shift circuit 9; switching elements 1 and 2; diodes 3, 4, and 8; a resistor 5; and a zener diode 7. The level shift circuit is composed of: two N-type transistors HVN1 and HVN2 whose sources are grounded to GND; and two P-type transistors HVP1 and HVP2 whose sources are connected to the high-voltage power supply VH. Drains of the N-type transistor HVN1 and the P-type transistor HVP2, a gate of the P-type transistor HVP2, and a gate of the switching element 1 are connected. Drains of the N-type transistor HVN2 and the P-type transistor HVP2 are connected, and they are connected to a gate of the P-type transistor HVP1.

The level-shift driving circuit 200 is composed of: two P-type transistors P1 and P2; an N-type transistor N1; and a delay element 10. Drains of the P-type transistors P1 and P2 and a drain of the N-type transistor N1 are connected to a gate of the N-type transistor HVN1 by a node C. Sources of the P-type transistors P1 and P2 are connected to the power source VDD. A source of the N-type transistor N1 is grounded to GND. A gate of the P-type transistor P2 and a gate of the N-type transistor N1 are connected to an output of the delay element 10 by a node B. A gate of the P-type transistor P1 is connected to an input signal IN1.

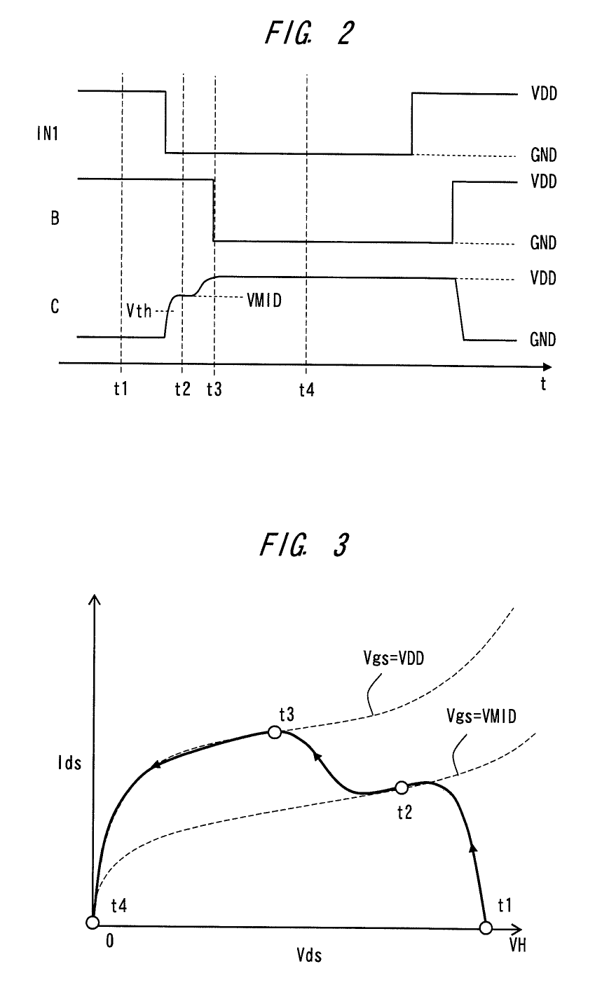

The circuit configured as described above will be described with reference to FIG. 2. First, at t1 of a steady state where the input signal IN1 is at a Hi level, as the P-type transistors P1 and P2 are OFF, the N-type transistor N1 is ON and the node C is at a Lo level, the N-type transistor HVN1 is OFF. When IN2 is at the Hi level and IN3 is at the Lo level, the N-type transistor HVN2 is ON, the P-type transistor HVP1 is ON, the P-type transistor HVP2 is OFF, the switching element 1 is ON, the switching element 2 is OFF, and an output DOUT is thus at the Hi level.

At t2 just after the input signal IN1 is switched to the Lo level, as the P-type transistor P1 is ON and the node B is at the Hi level, the P-type transistor P2 is OFF and the N-type transistor N1 is ON. Since both of the P-type transistor P1 and the N-type transistor N1 are ON, the node C is at an intermediate potential VMID between the GND level and VDD level. By setting the intermediate potential VMID at a level larger than a threshold voltage Vth of the N-type transistor HVN1, as well as ensuring a drain current sufficient to drive the switching element 1 for the N-type transistor HVN1, the drain current can be suppressed to a level capable of preventing the circuit from being inoperative due to the On withstand voltage. In addition, since the time to reach the intermediate potential VMID can be shortened, there is an advantage of shortening delay time also. As the N-type transistor HVN1 is turned ON, the gate capacitor of the switching element 1 is driven, so that a drain-source potential is gradually lowered. Since a gate-source voltage Vgs is suppressed to VMID that is lower than VDD, the drain current Ids is small, and thus the N-type transistor HVN1 is avoided to have large Vds and large Ids. The input signal IN2 is set to the Lo level so that the N-type transistor HVN2 is turned OFF, thereby inverting the level shift.

Since the input signal IN1 is at the Lo level at a time t3 in FIG. 2, the P-type transistor P1 is turned ON. Since the node B is also at the Lo level, the P-type transistor P2 is ON and the N-type transistor N1 is OFF. The node C becomes VDD so that the drain current Ids of the N-type transistor HVN1 becomes large, so the drain-source voltage Vds of the N-type transistor HVN1 is dropped to the Lo level quickly, thereby turning OFF the switching element quickly. At a time t4, it is in a steady state where the N-type transistor HVN1 is ON.

The input signal IN3 is set to the Hi level at timing not to turn ON the switching elements 1 and 2 at the same time, and the output DOUT is fixed to the Lo level.

In FIG. 3, operation points of the N-type transistor HVN1 from t1 to t4 are illustrated. The horizontal axis indicates the drain-source voltage Vds, and the vertical axis indicates the drain current Ids. At the time t1, Vds=VH and Ids=0. At the time t2, the drain current Ids reaches a saturation current suppressed with the gate-source voltage Vgs=VMID, so that the drain-source voltage Vds is lowered with the suppressed saturation current Ids. Via a large saturation current with Vgs=VDD at the time t3, it reaches the time t4 at which Vds=0 and Ids=0. The state where Vds is large and also Ids is large is avoided, thereby preventing the circuit from being inoperative due to a lack of an On withstand margin.

In the manner described above, in the level shift circuit in FIG. 1, the state where the drain current of the N-type transistor HVN1 which drives the switching element 1 is large and also the drain-source voltage is large is avoided, so that a breakdown due to a lack of the On withstand voltage of the N-type transistor HVN1 is prevented.

### First Modification Example of First Embodiment

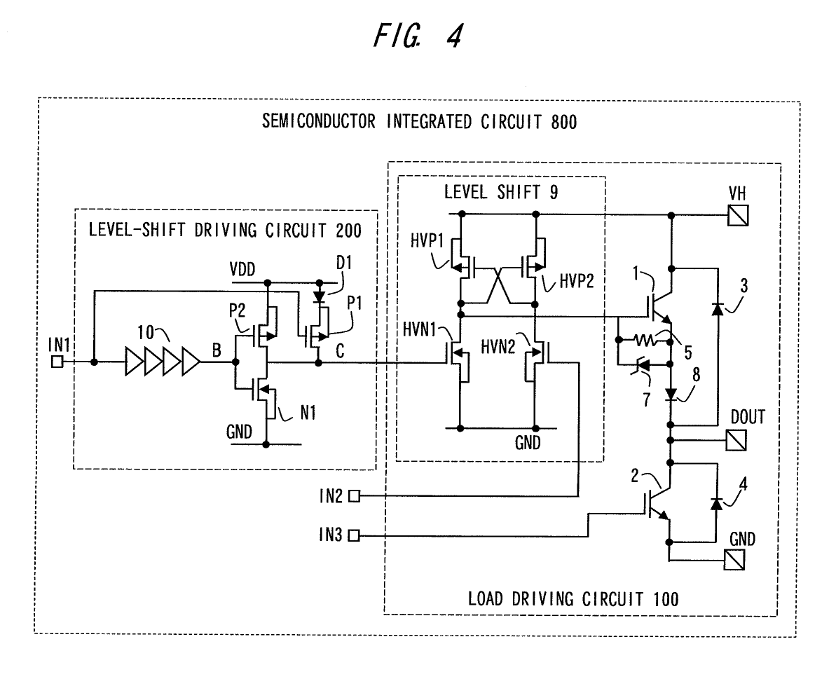

FIG. 4 is a diagram illustrating a first modification example that is a modification example of the first embodiment.

The present modification example is a one in which a change is applied to the level-shift driving circuit 200 of the first embodiment. More specifically, a diode D1 is connected between the source of the P-type transistor P1 and the power supply VDD. Accordingly, the potential of the node C is lowered by a voltage drop by the diode D1 when the P-type transistor P1 and the N-type transistor N1 are turned ON at the same time, so that a gate voltage increase of the N-type transistor HVN1 can be suppressed.

While the operation of the circuit will be omitted because it is same with the first embodiment, the state where the drain current of the N-type transistor HVN1 which drives the switching element 1 is large and also the drain-source voltage is large is avoided in the circuit in FIG. 4 configured as described above, thereby preventing the circuit from being inoperative due to a lack of the On withstand voltage of the N-type transistor HVN1.

### Second Modification Example of First Embodiment

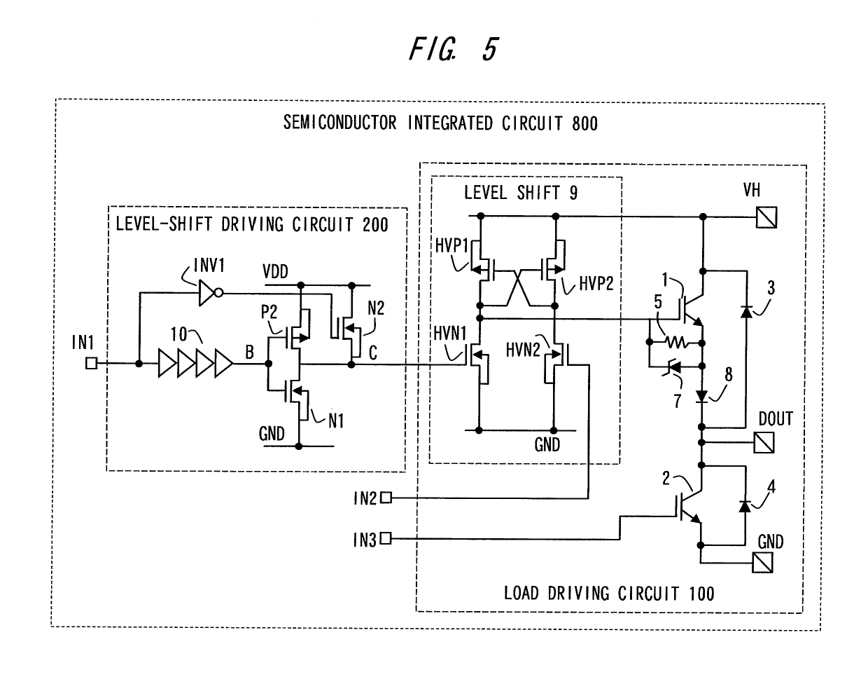

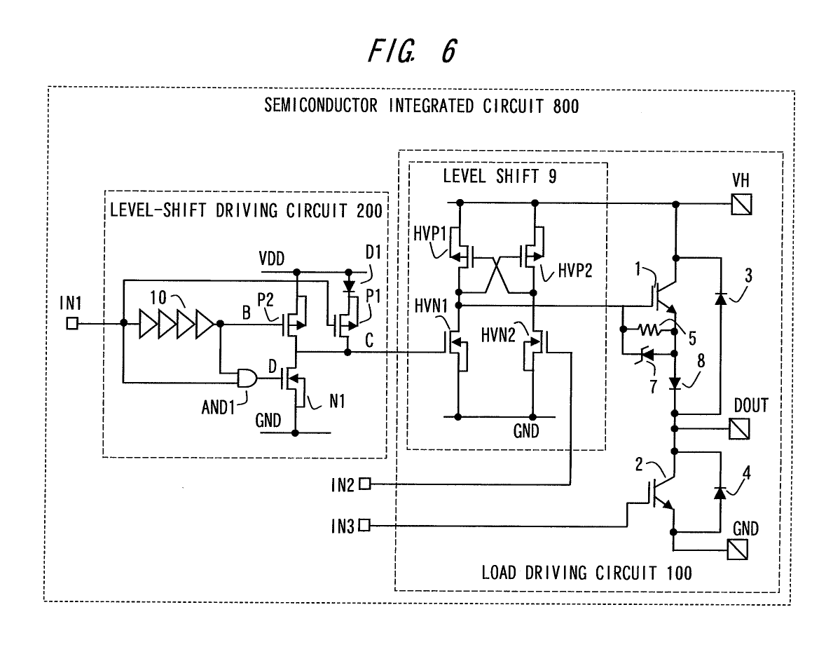

FIG. 5 is a diagram illustrating a second modification example that is another modification example of the first embodiment.

The present modification example is another modification example in which a change is applied to the level-shift driving circuit 200 of the first embodiment. An N-type transistor N2 is connected between the power source VDD and the node C instead of the P-type transistor P1 so that its drain is connected to VDD and its source is connected to the node C. In addition, an inverter INV1 is connected between the input signal IN1 and the gate of the N-type transistor N2 so that its input is connected to the input signal IN1 and its output is connected to the gate of the N-type transistor N2.

Descriptions about operations of the input signal IN1, node B, and node C will be omitted because they are same with those of the first embodiment. Meanwhile, the potential of the node C upon turning ON the N-type transistor N1 and the N-type transistor N2 at the same time is lowered by a threshold voltage of the N-type transistor N2, so that a gate voltage increase of the N-type transistor HVN1 can be suppressed.

The state where the drain current of the N-type transistor HVN1 which drives the switching element 1 is large and also the drain-source voltage is large is avoided in the circuit in FIG. 5 configured as described above, thereby preventing the circuit from being inoperative due to a lack of On withstand voltage of the N-type transistor HVN1.

### Second Embodiment

FIG. 6 is a diagram illustrating a second embodiment that is another example of a semiconductor integrated circuit device of the present invention.

A semiconductor integrated circuit device 800 of the present embodiment is composed of two parts of: a level-shift driving circuit 200 to which a voltage VDD of about 5 V is applied; and a load driving circuit to which a high power supply VH higher than or equal to 100 V is applied. As the load driving circuit 100 is same with that of the first embodiment, descriptions thereof is omitted here. The level-shift driving circuit 200 is composed of: two P-type transistors P1 and P2; an N-type transistor N1; a diode D1; an AND element AND1; and a delay element 10. A gate of an N-type transistor HVN1 composing a level shift 9 is connected to a drain of the P-type transistor P1, a drain of the P-type transistor P2, a drain of the N-type transistor N1, and a node C. A source of the P-type transistor P2 is connected to the power source VDD. A source of the N-type transistor N1 is grounded to GND. The diode D1 is connected to the source of the P-type transistor P1 and the power source VDD. The delay element 10 is connected to an input signal IN1 and a node B. The AND element AND1 is connected to the input signal IN1 with taking the node B as input. An output node D of the AND element AND1 is connected to the gate of the N-type transistor N1.

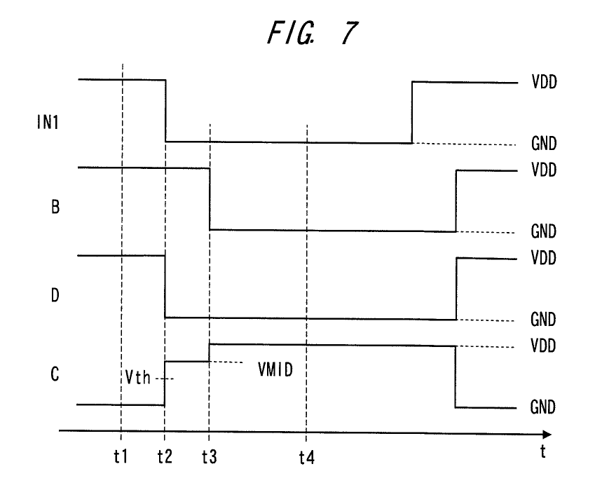

Hereinafter, operations of the circuit configured as described above will be described with reference to FIG. 7. First, at t1 of a steady state where the input signal IN1 is at a Hi level (high level), the P-type transistors P1 and P2 are OFF, the N-type transistor N1 is ON, and the node C is at a Lo level (low level). When an input signal IN2 is at the Hi level and an input signal IN3 is at the Lo level, the N-type transistor HVN2 is ON, the P-type transistor HVP1 is ON, the P-type transistor HVP2 is OFF, the switching element 1 is ON, and the switching element 2 is OFF, so that the output DOUT is at the Hi level.

In a time period from a time t2 at which the input signal IN1 is switched from the Hi level to the Lo level to a time t3 at which the output node B of the delay element 10 is switched to the Lo level, the P-type transistor P1 is ON, the P-type transistor P2 is OFF, and the N-type transistor N1 is OFF. A potential of the node C is VMID that is lower than VDD by a voltage drop by the diode D1. By setting VMID to a level larger than a threshold voltage Vth of the N-type transistor HVN1 composing the level shift 9, as well as ensuring a drain current sufficient for the N-type transistor HVN1 to drive the switching element 1, the drain current can be suppressed to a level capable of preventing the circuit from being inoperative due to an On withstand voltage of the N-type transistor HVN1. In addition, since the time to reach VMID can be shortened, there is an advantage of shortening a delay time also. As the N-type transistor HVN1 is turned ON, a gate capacitor of the switching element 1 is driven, so that a drain-source potential is gradually lowered. In this manner, the N-type transistor HVN1 is avoided to have a state where the drain-source voltage Vds is large and also the drain current Ids is large. The input signal IN2 is set to the Lo level so that the N-type transistor HVN2 is OFF, thereby helping an inversion of the level shift.

As the input signal IN1 is at the Lo level immediately after the time t3 in FIG. 7, the P-type transistor P1 is ON. As the node B is also at the Lo level, the P-type transistor P2 is ON. As the node D is also at the Lo level, the N-type transistor N1 is OFF. The node C becomes VDD so that the drain current of the N-type transistor HVN1 becomes large, so the drain-source voltage Vds of the N-type transistor HVN1 is quickly dropped to the Lo level, thereby quickly turning OFF the switching element 1. At a time t4, it is in a steady state where the N-type transistor HVN1 is ON.

The input signal IN3 is set to the Hi level at timing at which the switching elements 1 and 2 are not turned ON at the same time, and the output DOUT is fixed to the Lo level.

In the manner described above, in the level shift circuit in FIG. 6, the state where the drain current of the N-type transistor HVN1 which drives the switching element 1 is large and also the drain-source voltage is large is avoided, so that a breakdown due to a lack of the On withstand voltage of the N-type transistor HVN1 is prevented.

### First Modification Example of Second Embodiment

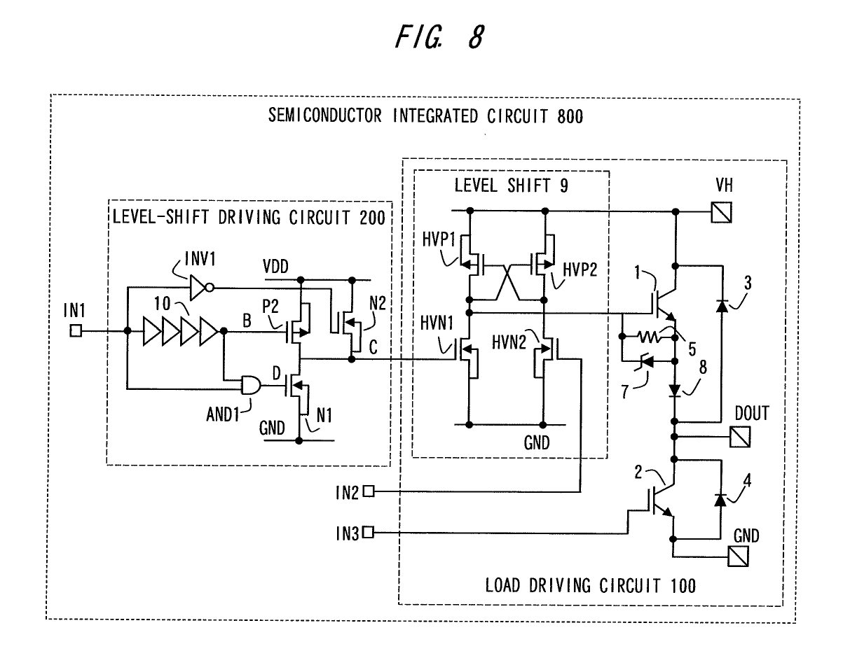

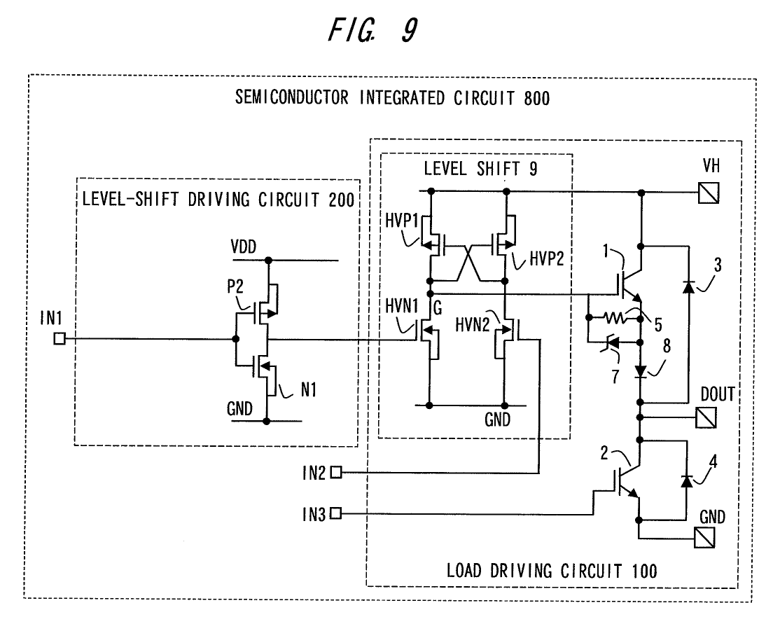

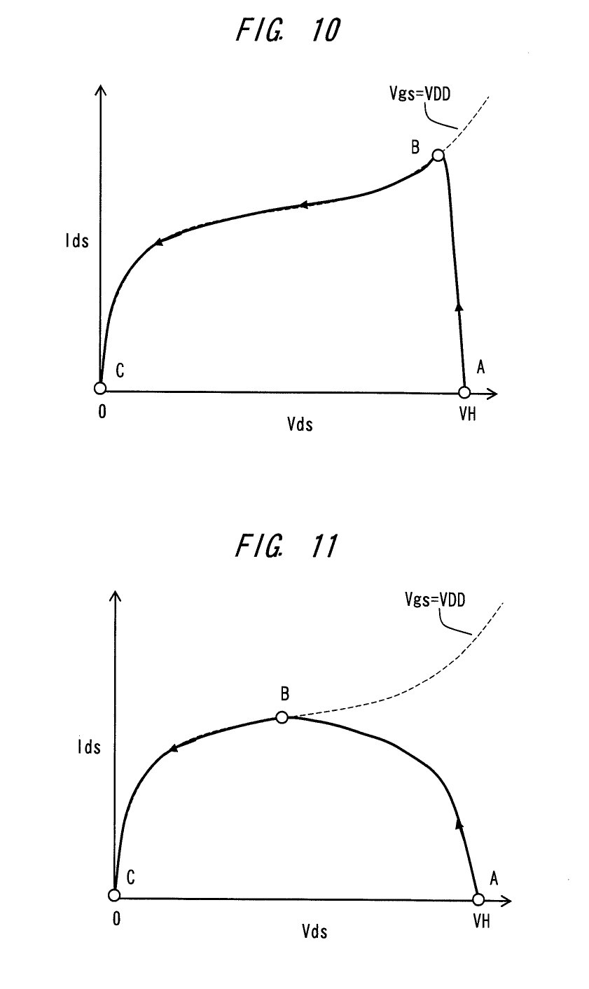

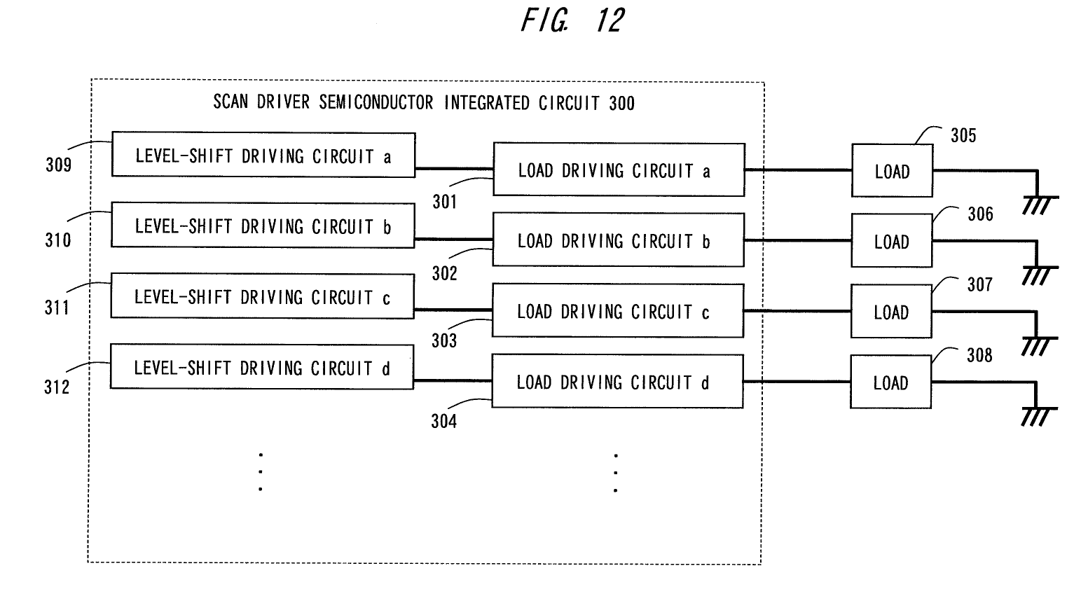

FIG. 8 is a diagram illustrating a first modification example that is a modification example of the second embodiment described above.

The present modification example is a one in which a change is applied to the level-shift driving circuit 200 of the second embodiment. More specifically, the source of the N-type transistor N2 is connected to the node C, and the drain of the N-type transistor N2 is connected to the power supply VDD. An inverter INV1 is connected between the gate of the N-type transistor N2 and the input signal IN1.

Descriptions about operations of the input signal IN1, node B, node D, and node C will be omitted because they are same with those of the second embodiment. Meanwhile, the potential of the node C when the N-type transistor N2 is ON, the P-type transistor P1 is OFF, and the N-type transistor N1 is OFF is lowered by a threshold voltage of the N-type transistor N2, so that a gate voltage increase of the N-type transistor HVN1 composing the level shift 9 can be suppressed.

The state where the drain current of the N-type transistor HVN1 which drives the switching element 1 is large and also the drain-source voltage is large is avoided in the circuit in FIG. 8 configured as described above, thereby preventing the circuit from being inoperative due to a lack of an On withstand voltage of the N-type transistor HVN1.

### Third Embodiment

A scan-driver semiconductor integrated circuit 300 of a third embodiment has a configuration in which a plurality of series connections of the load driving circuit 100 and the level-shift driving circuit 200 described in any one of FIGS. 1, 4, 5, 6, and 8 are arranged in parallel. Individual level-shift driving circuit “a” to “d” (309 to 312) respectively drives the level shift 9 composing respectively corresponding individual load driving circuit “a” to “d” (301 to 304). And, the individual load driving circuit a to d (301 to 304) respectively drives individual load 305 to 308, each of them configures one set of output bit.

### Fourth Embodiment

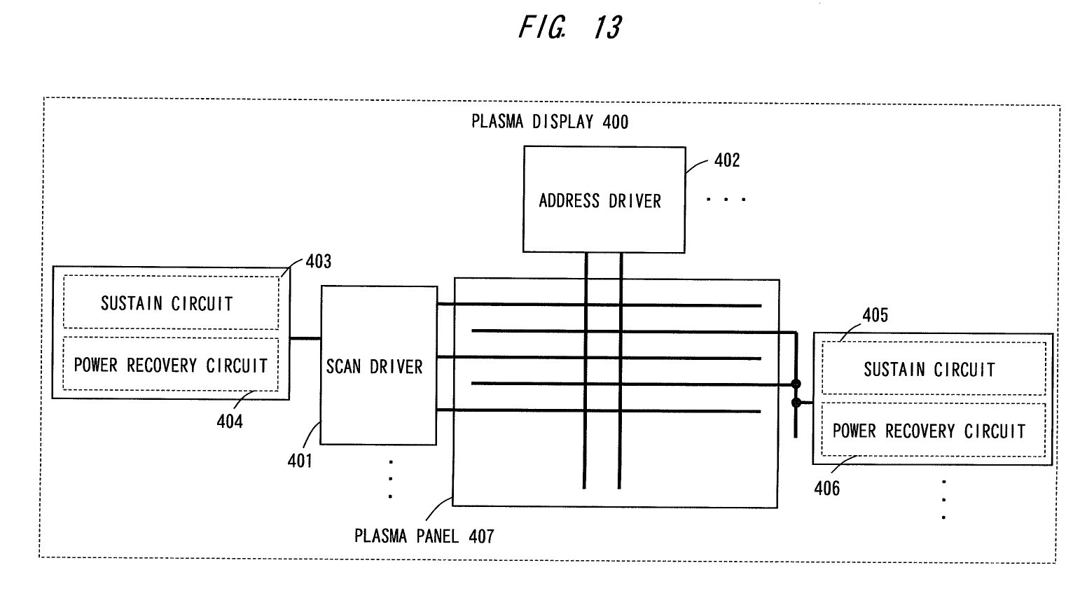

FIG. 13 is a diagram illustrating an embodiment of a plasma display applied with a semiconductor integrated circuit device in which one or a plurality of sets of the series connections of the load driving circuit 100 and the level-shift driving circuit 200 of the present invention are integrated and mounted on a common semiconductor substrate. In FIG. 13, a plasma display device 400 is composed of: a scan driver 401; an address driver 402; sustain circuits 403 and 405; and power recovery circuits 404 and 406. The scan driver 401 is connected to scanning lines running in a horizontal direction on a plasma panel 407, the address driver 402 is connected to data lines running in a vertical direction on the plasma panel 407, and the sustain circuit 405 is connected to sustain lines running in the horizontal direction on the plasma panel 407.

An emitting period of the plasma panel 407 is sectioned into a scan period and a sustain period. In the scan period, the scan driver sequentially lowers the scan lines from a Hi potential to a Lo potential. At this time, there is no scan lines lowered at the same time, and only one scan line is lowered to the Lo potential at one time. The address driver 402 supplies chromatic information at a position in the plasma panel 407 lowered to the Lo level by the scan driver 401 to the data line. A cross point of the scan line lowered to the Lo level by the scan driver 401 and the data line to which chromatic information is supplied by the address driver 402 is emitted by a preliminary discharge. After completing preliminary discharges at all positions in the plasma panel 407, the emitting period is shifted to the sustain period. In the sustain period, the emission of the preliminary discharge made in the scan period is continuously performed, so that an image is displayed on the plasma panel 407.

In the foregoing, the invention made by the inventors of the present invention has been concretely described based on the embodiments. However, it is needless to say that the present invention is not limited to the foregoing embodiments and various modifications and alterations can be made within the scope of the present invention.

What is claimed is:

1. A semiconductor integrated circuit device comprising:
an output terminal;
a load driving circuit including an output transistor connected to the output terminal, and a level shift circuit that changes an input level of the output transistor;
a level-shift driving circuit including a first inverter in which a second P-type MOS transistor whose source is connected to a first power supply and a first N-type MOS transistor whose source is connected to a second power supply whose potential is lower than that of the first power supply are connected via each other's drains; and
an input terminal commonly connected electrically to gates of the second P-type MOS transistor and the first N-type MOS transistor composing the first inverter,
wherein the level shift circuit includes first and second load driving N-type MOS transistors whose sources are commonly connected electrically to the second power supply, and a drain of the first load driving N-type transistor is connected to a gate of the output transistor, and
wherein the level-shift driving circuit is connected to a gate of the first load driving circuit composing the level shift circuit through the common drain of the first inverter, and includes a level-shift driving voltage suppressing circuit which suppresses a voltage generated at the common drain of the first inverter.

2. The semiconductor integrated circuit device according to claim 1,
wherein the level-shift driving voltage suppressing circuit includes:
a first P-type MOS transistor whose source is electrically connected to the first power supply, whose drain is connected to the common drain of the first inverter, and whose gate is connected to the input terminal; and
a delay element whose output is commonly connected to the gates of the second P-type MOS transistor and the first NMOS transistor composing the first inverter, and whose input is connected to the input terminal.

3. The semiconductor integrated circuit device according to claim 2,
wherein the first P-type MOS transistor is electrically connected to the first power supply via a diode whose anode is connected to the first power supply and whose cathode is connected to the source of the first P-type MOS transistor.

4. The semiconductor integrated circuit device according to claim 1,
wherein the level-shift driving voltage suppressing circuit includes:
a second N-type MOS transistor whose drain is electrically connected to the first power supply, whose source is connected to the common drain of the first inverter, and whose gate is electrically connected to the input terminal via a second inverter; and
a delay element whose output is commonly connected to the gates of the second P-type MOS transistor and the first N-type MOS transistor composing the first inverter, and whose input is connected to the input terminal.

5. The semiconductor integrated circuit device according to claim 1,
wherein the level-shift driving voltage suppressing circuit includes:
a first P-type MOS transistor whose source is electrically connected to the first power source, whose drain is connected to the common drain of the first inverter, and whose gate is connected to the input terminal;
a delay element whose output is connected to the gate of the second P-type MOS transistor composing the first inverter, and whose input is connected to the input terminal; and
an AND gate element whose output is connected to the gate of the first N-type MOS transistor composing the first inverter, and whose input is connected to the input terminal and the output of the delay element, and
wherein the first P-type MOS transistor is electrically connected to the first power supply via a diode whose anode is connected to the first power supply, and whose cathode is connected to the source of the first P-type MOS transistor.

6. The semiconductor integrated circuit device according to claim 1,
wherein the level-shift driving voltage suppressing circuit includes:
a second N-type MOS transistor whose drain is electrically connected to the first power source, whose source is connected to the common drain of the first inverter, and whose gate is electrically connected to the input terminal via a second inverter;
a delay element whose output is connected to the gate of the second P-type MOS transistor composing the first inverter, and whose input is connected to the input terminal; and
an AND gate element whose output is connected to the gate of the first N-type MOS transistor composing the first inverter, and whose input is connected to the input terminal and the output of the delay element.

7. A semiconductor integrated circuit device which is a circuit supplying high and low voltages to a load, comprising:
a first semiconductor switching element connected between a first power supply and an output terminal;
a second semiconductor switching element connected between the output terminal and a second power supply whose potential is lower than that of the first power supply;
a first high-voltage PMOS transistor driving a gate of the first semiconductor switching element;
a first high-voltage NMOS transistor driving the gate of the first semiconductor switching element;
a second high-voltage PMOS transistor differentially operated with the first high-voltage PMOS transistor;
a second high-voltage NMOS transistor differentially operated with the first high-voltage NMOS transistor; and
a level-shift driving circuit including a first inverter in which a second P-type MOS transistor whose source is connected to the first power supply and a first N-type MOS transistor whose source is connected to the second power supply are connected via each other's drains, and a level-shift driving voltage suppressing circuit suppressing a voltage applied to a gate of the first high voltage N-type MOS transistor.

8. The semiconductor integrated circuit device according to claim 7,
wherein the level-shift driving voltage suppressing circuit includes:
a first P-type MOS transistor whose source is electrically connected to the first power supply, whose drain is connected to the common drain of the first inverter, and whose gate is connected to the input terminal; and
a delay element whose output is commonly connected to the gates of the second P-type MOS transistor and the first NMOS transistor composing the first inverter, and whose input is connected to the input terminal.

9. The semiconductor integrated circuit device according to claim 8,
wherein the first P-type MOS transistor is electrically connected to the first power supply via a diode whose anode is connected to the first power supply and whose cathode is connected to the source of the first P-type MOS transistor.

10. The semiconductor integrated circuit device according to claim 7,
wherein the level-shift driving voltage suppressing circuit includes:
a second N-type MOS transistor whose drain is electrically connected to the first power supply, whose source is connected to the common drain of the first inverter, and whose gate is electrically connected to the input terminal via a second inverter; and
a delay element whose output is commonly connected to the gates of the second P-type MOS transistor and the first N-type MOS transistor composing the first inverter, and whose input is connected to the input terminal.

11. The semiconductor integrated circuit device according to claim 7,
wherein the level-shift driving voltage suppressing circuit includes:
a first P-type MOS transistor whose source is electrically connected to the first power source, whose drain is connected to the common drain of the first inverter, and whose gate is connected to the input terminal;
a delay element whose output is connected to the gate of the second P-type MOS transistor composing the first inverter, and whose input is connected to the input terminal; and
an AND gate element whose output is connected to the gate of the first N-type MOS transistor composing the first inverter, and whose input is connected to the input terminal and the output of the delay element, and
wherein the first P-type MOS transistor is electrically connected to the first power supply via a diode whose anode is connected to the first power supply, and whose cathode is connected to the source of the first P-type MOS transistor.

12. The semiconductor integrated circuit device according to claim 7,
wherein the level-shift driving voltage suppressing circuit includes:
a second N-type MOS transistor whose drain is electrically connected to the first power source, whose source is connected to the common drain of the first inverter, and whose gate is electrically connected to the input terminal via a second inverter;
a delay element whose output is connected to the gate of the second P-type MOS transistor composing the first inverter, and whose input is connected to the input terminal; and
an AND gate element whose output is connected to the gate of the first N-type MOS transistor composing the first inverter, and whose input is connected to the input terminal and the output of the delay element.

13. A semiconductor integrated circuit device comprising a plurality of sets of circuits arranged in parallel and integrally formed on a common semiconductor substrate, the circuit composed of:
an output terminal;
a load driving circuit including an output transistor connected to the output terminal and a level shift circuit that changes an input level of the output transistor;
a level-shift driving circuit including a first inverter in which a second P-type MOS transistor whose source is connected to a first power supply and a first N-type MOS transistor whose source is connected to a second power supply whose potential is lower than that of the first power supply are connected via each other's drains; and
an input terminal commonly connected electrically to gates of the second P-type MOS transistor and the first N-type MOS transistor composing the first inverter,
wherein, in each of the plurality of sets of circuits,
wherein the level shift circuit includes first and second load driving N-type MOS transistors whose sources are commonly connected electrically to the second power supply, and a drain of the first load driving N-type transistor is connected to a gate of the output transistor, and
wherein the level-shift driving circuit is connected to a gate of the first load driving circuit composing the level shift circuit via the common drain of the first inverter, and includes a level-shift driving voltage suppressing circuit which suppresses a voltage generated at the common drain of the first inverter.

14. The semiconductor integrated circuit device according to claim 13,
wherein the level-shift driving voltage suppressing circuit includes:
a first P-type MOS transistor whose source is electrically connected to the first power supply, whose drain is connected to the common drain of the first inverter, and whose gate is connected to the input terminal; and
a delay element whose output is commonly connected to the gates of the second P-type MOS transistor and the first NMOS transistor composing the first inverter, and whose input is connected to the input terminal.

15. The semiconductor integrated circuit device according to claim 14,
wherein the first P-type MOS transistor is electrically connected to the first power supply via a diode whose anode is connected to the first power supply and whose cathode is connected to the source of the first P-type MOS transistor.

16. The semiconductor integrated circuit device according to claim 13,
wherein the level-shift driving voltage suppressing circuit includes:
a second N-type MOS transistor whose drain is electrically connected to the first power supply, whose source is connected to the common drain of the first inverter, and whose gate is electrically connected to the input terminal via a second inverter; and
a delay element whose output is commonly connected to the gates of the second P-type MOS transistor and the first N-type MOS transistor composing the first inverter, and whose input is connected to the input terminal.

17. The semiconductor integrated circuit device according to claim 13,
wherein the level-shift driving voltage suppressing circuit includes:
a first P-type MOS transistor whose source is electrically connected to the first power source, whose drain is connected to the common drain of the first inverter, and whose gate is connected to the input terminal;
a delay element whose output is connected to the gate of the second P-type MOS transistor composing the first inverter, and whose input is connected to the input terminal; and
an AND gate element whose output is connected to the gate of the first N-type MOS transistor composing the first inverter, and whose input is connected to the input terminal and the output of the delay element, and
wherein the first P-type MOS transistor is electrically connected to the first power supply via a diode whose anode is connected to the first power supply, and whose cathode is connected to the source of the first P-type MOS transistor.

18. The semiconductor integrated circuit device according to claim 13,
wherein the level-shift driving voltage suppressing circuit includes:
a second N-type MOS transistor whose drain is electrically connected to the first power source, whose source is connected to the common drain of the first inverter, and whose gate is electrically connected to the input terminal via a second inverter;
a delay element whose output is connected to the gate of the second P-type MOS transistor composing the first inverter, and whose input is connected to the input terminal; and
an AND gate element whose output is connected to the gate of the first N-type MOS transistor composing the first inverter, and whose input is connected to the input terminal and the output of the delay element.
